(19) United States
(12) Patent Application Publication
(10) Pub. No.: US 2009/0243042 A1
(43) Pub. Date: Oct. 1, 2009

(54) LATERAL SEMICONDUCTOR DEVICE

(76) Inventors: Kiyoharu HAYAKAWA, Obu-city (JP); Masato TAKI, Nishikamo-gun (JP)

Correspondence Address: KENYON & KENYON LLP, 1500 K STREET N.W., SUITE 700, WASHINGTON, DC, 20005, US

(21) Appl. No.: 12/408,309

(22) Filed: Mar. 20, 2009

(30) Foreign Application Priority Data
Mar. 28, 2008 (JP) 2008-088664

(51) Int. Cl. H01L 29/735

(52) U.S. Cl. 257/565; 257/E29.187

(57) ABSTRACT

A semiconductor device has a first main electrode and a second main electrode that are provided on a semiconductor layer. The semiconductor layer has: an n type first semiconductor region in contact with the first main electrode; a p type second semiconductor region in contact with the second main electrode; and an n type third semiconductor region provided between the first and second semiconductor regions. The third semiconductor region has a first layer and a second layer. The impurity concentration in the first layer is uniform. The second layer has a higher impurity concentration than the first layer that increases in a gradient from the first semiconductor region to the second semiconductor region.

### INCORPORATION BY REFERENCE

The disclosure of Japanese Patent Application No. 2008-088664 filed on Mar. 28, 2008, including the specification, drawings and abstract is incorporated herein by reference in its entirety.

### BACKGROUND OF THE INVENTION

1. Field of the Invention

The invention relates to a lateral bipolar semiconductor device.

2. Description of the Related Art

Japanese Patent Application Publication No. 04-309234 (JP-A-04-309234) describes a laterally-diffused metal oxide semiconductor (LDMOS). The LDMOS is characterized in that the impurity concentration in the drift region increases in the lateral direction from the source side to the drain side. If the impurity concentration in the drift region increases in the lateral direction, the electric field distribution in the drift region becomes uniform in the lateral direction. Techniques for increasing the impurity concentration in the drift region in the lateral direction are important to increase the withstand voltage.

However, if the above-described technology is used in a lateral bipolar semiconductor device, the following problem arises.

In general, lateral bipolar semiconductor devices are characterized in their relatively low ON voltages (ON resistances) that are obtained through activation of electric conductivity modulations in drift regions. Electric conductivity modulations are activated in regions where the impurity concentration is low. According to the technology described above, because the impurity concentration in the drift region increases in the lateral direction, there exists, on one end of the drift region, a region where the impurity concentration is high. When such a high-impurity-concentration region exists in the drift region, electric conductivity modulations are not activated. That is, if such a high-impurity-concentration region exists in a portion of the drift region as viewed in the lateral direction thereof, electric conductivity modulations are not activated even if the impurity concentrations in other portions of the drift region are low. Therefore, if the technology of JP-A-4-309234 is used in a lateral bipolar semiconductor device as it is, the ON voltage (ON resistance) of the semiconductor device deteriorates significantly.

### SUMMARY OF THE INVENTION

The invention provides a technology for reducing the ON voltage (ON resistance) of a lateral bipolar semiconductor device while maintaining its withstand voltage.

The lateral semiconductor device described in the present specification has a drift region that includes a layer in which the impurity concentration increases laterally and a layer in which the impurity concentration is low. The former layer of the drift region makes the electric field distribution uniform in the lateral direction of the drift region when the lateral semiconductor device is off, while the latter layer of the drift region activates electric conductivity modulations in the drift region. Having these two layers in the drift region improves both the withstand voltage and the ON voltage (ON resistance) of the lateral semiconductor device.

The first aspect of the invention relates to a lateral bipolar semiconductor device. The semiconductor device includes: a semiconductor layer; a first main electrode that is provided over a portion of the upper face of the semiconductor layer; and a second main electrode that is provided over another portion of the upper face of the semiconductor layer. The semiconductor layer includes a first semiconductor region of a first conductivity type that is in contact with the first main electrode; a second semiconductor region of a second conductivity type that is in contact with the second main electrode; and a third semiconductor region of the first conductivity type that is provided between the first semiconductor region and the second semiconductor region. The third semiconductor region inlcudes a first layer and a second layer that extend in a first direction running through the first semiconductor region and the second semiconductor region and that are aligned in a second direction, perpendicular to the first direction. The impurity concentration in the first layer is uniform in the first direction. The impurity concentration in the second layer is higher than that in the first layer, and the impurity concentration in the second layer increases from the first semiconductor region side to the second semiconductor region side. Note that “aligned in a second direction perpendicular to the first direction” refers also to a case where a plurality of the first layers and a plurality of the second layers are aligned in the second direction.

The above-described lateral bipolar semiconductor device may be such that the semiconductor layer is an active layer of a laminated substrate constituted of a semiconductor substrate, an implanted insulation layer, and an active layer. That is, if an active layer of a laminated substrate is used, a semiconductor device with a higher withstand voltage may be obtained.

Furthermore, the second layer may be in contact with the implanted insulation layer, and the first layer may be provided on the second layer. That is, the first layer may be provided in the upper side of the active layer. Because the impurity concentration in the first layer is lower than the impurity concentration in the second layer, electric conductivity modulations are more likely to occur in the first layer than in the second layer. Typically, in a lateral semiconductor device, main electrodes (e.g., emitter electrode and collector electrode) are provided in the surface of the active layer. Therefore, the above-described structure causes electric conductivity modulations to occur in the shortest path of electric current.

Further, the second direction may include a laminating direction of the laminated substrate and a planar direction of each layer of the laminated substrate.

Further, the impurity concentration in the second layer may increase in a discontinuous gradient from the first semiconductor side to the second semiconductor side.

Alternatively, the impurity concentration in the second layer may increase in a continuous gradient from the first semiconductor side to the second semiconductor side.

According to the invention, as such, it is possible to reduce the ON voltage (ON resistance) of a lateral bipolar semiconductor device while maintaining its withstand voltage, and therefore a lateral bipolar semiconductor device having a high withstand voltage and having a low loss can be provided.

### BRIEF DESCRIPTION OF THE DRAWINGS

The foregoing and further features and advantages of the invention will become apparent from the following description of example embodiments with reference to the accompanying drawings, wherein like numerals are used to represent like elements and wherein:

FIG. 1 is a view schematically showing the cross section of a portion of a semiconductor device according to the first example embodiment of the invention;

FIG. 2 is a graph schematically illustrating the impurity concentration distribution in the drift region along II-II in FIG. 1;

FIG. 3 is a graph schematically showing the electric current distribution in the drift region of the semiconductor device of the first example embodiment

FIG. 4 is a perspective view of the drift region of the semiconductor device of the first example embodiment;

FIG. 5 is a perspective view of the drift region of a modified version of the semiconductor device of the first example embodiment;

FIG. 6 is a graph illustrating the results of a comparison between the current-voltage characteristic of the semiconductor device of the first example embodiment and the current-voltage characteristic of a semiconductor device according to related art;

FIG. 7 is a view showing the cross section of a portion of a semiconductor device of the modified version of the semiconductor device of the first example embodiment; and

FIG. 8 is a view schematically showing the cross section of a portion of a semiconductor device according to a related art.

### DETAILED DESCRIPTION OF THE EMBODIMENTS

The impunity concentration in the second layer increases non-continuously (in steps) toward the collector region. That is, the impurities that have been ion-implanted into the second layer may be activated without treating them at a high temperature for a long period of time. Therefore, the production equipment for the semiconductor device can be simplified. The second layer may be formed by ion-implantation of impurities into the active layer of a laminated substrate. The first layer is a portion of the drift region where the second layer is not formed. This is how the first layer and the second layer are formed.

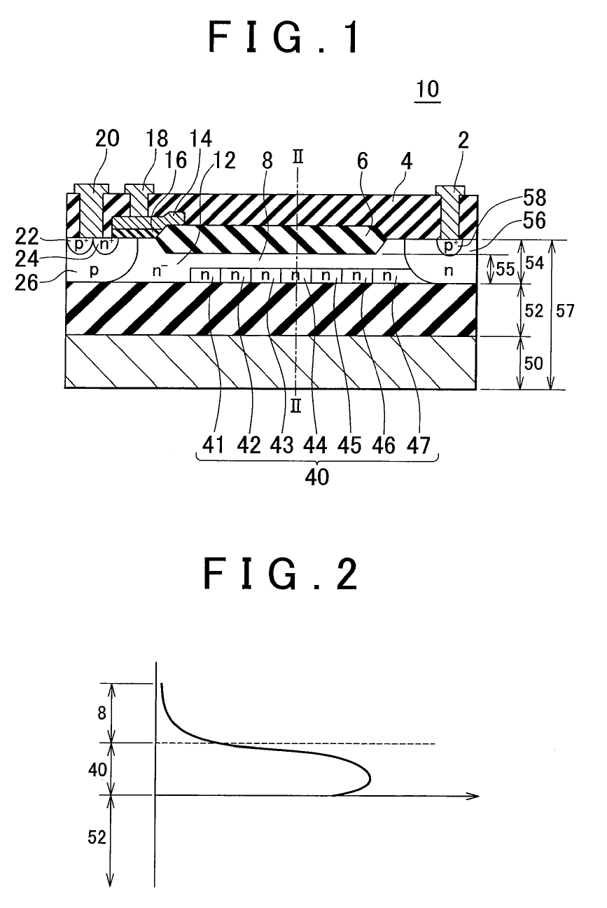

FIG. 1 schematically shows the cross section of portion of the semiconductor device 10. The semiconductor device 10 comprises a p-type semiconductor substrate 50, an implanted insulation layer 52 provided over the semiconductor substrate 50, and an active layer 54 that is provided over the implanted insulation layer 52. The semiconductor substrate 50 is made mainly of silicon, and its impurity concentration is adjusted to approx. 3×10¹⁸ cm⁻³. The potential of the semiconductor substrate 50 is fixed at the ground potential. The implanted insulation layer 52 is made mainly of oxidized silicon, and its thickness is approx. 4 μm. The active layer 54 is made mainly of silicon, and its impurity concentration is adjusted to approx. 1×10¹⁵ cm⁻³ before semiconductor structures are formed therein. The semiconductor device 10 is produced by ion-implantation of impurities into the active layer 54 of the laminated substrate 57.

The semiconductor device 10 is a lateral Integrated Gate Bipolar Transistor (ICBT), having an n⁺ type emitter region 24, a p⁺ type collector region 58, and an n type drift region 12. The emitter region 24 is provided on a portion of the upper face of the active layer 54. A p type body region 26 that partitions the emitter region 24 from the drift region 12 surrounds the emitter region 24. The body region 26 extends from the upper face to the bottom face of the active layer 54. A body-side contact region 22 is formed in the upper face of the active layer 54 as part of the body region 26. The emitter region 24 and the body-side contact region 22 are in contact with an emitter electrode 20. That is, the emitter region 24 and the body-side contact region 22 are electrically connected to the emitter electrode 20. The impurity concentration in the emitter region 24 is adjusted to approx. 1×10¹⁹ to 1×10²¹ cm^{-3.} The impurity concentration in the body region 26 is adjusted to approx. 5×10¹⁶ to 5×10¹⁷ cm⁻³. The impurity concentration in the body-side contact region 22 is adjusted to approx. 1×10¹⁹ to 1×10²¹ cm⁻³. Note that the emitter electrode 20 may be regarded as one example of “first main electrode” cited in the claims.

The collector region 58 is provided on a portion of the upper face of the active layer 54. The collector region 58 is in contact with a collector electrode 2. That is, the collector region 58 is electrically connected to the collector electrode 2. The collector region 58 is surrounded by an n type buffer region 56, partitioning the collector region 58 and the drift region 12. The buffer region 56 extends from the upper face to the bottom face of the active layer 54. The impurity concentration in the collector region 58 is adjusted to approx. 5×10¹⁶ to 5×10¹⁷ cm^{-3.}

The drift region 12 is provided between the body region 26 and the buffer region 56. One end of the drift region 12 is in contact with the body region 26, and the other end is in contact with the buffer region 56. The drift region 12 has a first layer 8 and a second layer 40 both extending laterally. The second layer 40 is the portion of the drift region 12 into which impurities have been ion-implanted, and the first layer 8 is the portion of the drift region 12 into which no impurities have been ion-implanted. As such, the impurity concentration in the first layer 8 is approx. 1×10¹⁵ cm^{-3.} The impurity concentration in the second layer 40 increases toward the collector region 58. That is, the impurity concentration in the second layer 40 increases from the portion 41 to the portion 47 of the second layer 40 in the ascending order of the portions 41, 42, 43, 44, 45, 46, and 47. In this example embodiment, although the impurity concentration in the second layer 40 increases discontinuously (i.e., in steps) toward the collector region 58; however, the concentration may also be increased toward the collector region 58 in a continuous manner. A field insulation membrane 6 is provided on a portion of the upper face of the drift region 12.

A gate electrode 14 is provided that faces, via a gate insulation membrane 16, the body region 26 partitioning the emitter region 24 from the drift region 12. The gate electrode 14 is made of polysilicon and contains impurities (phosphorus) that have been ion-implanted into the gate electrode 14. The impurity concentration of the gate electrode 14 is adjusted to approx. 1×10²⁰ cm⁻³, and therefore the gate electrode 14 is regarded as being conductive. A gate wire 18 is connected to the gate electrode 14. An interlayer insulation membrane 4 is provided on the upper face of the active layer 54. The interlayer insulation membrane 4 prevents short-circuits between the emitter electrode 20, the collector electrode 2, and the gate electrode 14.

Hereinafter, the drift region 12 will be described in greater detail. As indicated above, the second layer 40 is formed by ion-implantation of impurities (phosphorus) into the drift region 12. The impurity concentration in the second layer 40 discontinuously increases toward the collector region 58 over the seven portions, that is, the portions 41 to 47. No impurities have been ion-implanted into the portion of the drift region 12 near the body region 26. Thus, if this portion of the drift region 12 is counted in addition to the portions 41 to 47, it can be said that the impurity concentration in the drift region 12 discontinuously increases over 8 portions. The second layer 40 is formed by performing ion-implantation three times as follows. First, phosphorus ions are implanted into the portions 41, 43, 45, and 47 at a dose amount of 5×10¹¹ cm⁻² and at an acceleration voltage of 1.4 MeV. Next, phosphorus ions are implanted into the portions 42, 43, 46, and 47 at a dose amount of 1×10¹² cm⁻² and at an acceleration voltage of 1.4 MeV. Finally, phosphorus ions are implanted into the portions 44, 45, 46, and 47 at a dose amount of 2×10¹² cm⁻² and at an acceleration voltage of 1.4 MeV. As such, the dose amount of phosphorus ions varies by 5×10¹¹ cm⁻² each through the portions 41 to 47.

FIG. 2 schematically illustrates the impurity concentration distribution in the drift region 12 along II-II in FIG. 1. The vertical axis of the graph represents the position in the direction of the depth of the drift region 12 while the horizontal axis represents the impurity concentration. Note that the impurity concentration increases toward the right side of the graph of FIG. 2. As shown in FIG. 2, the impurity concentration in the second layer 40 is higher than the impurity concentration in the first layer 8. The boundary between the first layer 8 and the second layer 40 is the position at which the impurity concentration is below the impurity concentration at the contact face between the second layer 40 and the implanted insulation layer 52 by at least a single digit.

Hereinafter, the operation of the semiconductor device 10 will be described. When no voltage is being applied to the gate electrode 14, the body region 26 is present between the emitter region 24 and the drift region 12, and therefore electrons are unable to move from the emitter region 24 to the drift region 12. Thus, the semiconductor device 10 is off when no voltage is applied to the gate electrode 14. The semiconductor device 10 is a normally-off type semiconductor device. Voltage is applied to the collector electrode 2 as long as the semiconductor device 10 is off. Potential differences occur over the range from the collector region 58 to the emitter region 24. In general, the density of equipotential lines, which indicate constant electric field intensity differences, is higher in a high voltage area than in a low voltage area. In the case of the semiconductor device 10, however, because the impurity concentration of the second layer 40 increases toward the collector region 58, the intervals between the equipotential lines are even in the lateral direction throughout the entire drift region 12. As such, local electric field concentrations do not occur, and therefore the withstand voltage of the semiconductor device 10 can be increased.

When voltage is applied to the gate electrode 14, electron channels are created in the body region 26 between the emitter region 24 and the drift region 12, whereby electrons start moving from the emitter region 24 to the drift region 12. This is how the semiconductor device 10 is turned on. As the semiconductor device 10 is thus turned on, positive holes start moving from the collector region 58 to the drift region 12. As a result, the electrons moving from the emitter region 24 and the positive holes moving from the collector region 58 cause electric conductivity modulations in the drift region 12, so that the electric conductivity of the drift region 12 increases. That is, the resistances against the movements of carriers, that is, electrons and positive holes, decrease. In the semiconductor device 10, the first layer 8 in which the impurity concentration is lower than in the second layer 40 is provided so as to extend laterally in the drift region 12 as mentioned above, and this activates electric conductivity modulations that occur when the semiconductor device 10 is turned on. That is, because the impurity concentration in the first layer 8 is lower than that in the second layer 40, electric conductivity modulations tend to occur more in the first layer 8 than in the second layer 40. In other words, electric conductivity modulations tend to occur more in the upper side of the drift region 12 than in the lower side of the drift region 12. In other words, electric conductivity modulations end to occur at the shortest path between the emitter region 24 and the collector region 58, that is, the upper side of the drift region 12. According to the structure of the semiconductor device 10, thus, the resistance against the movement of carriers is lower than when the first layer 8 is provided in the lower side (i.e., the implanted insulation layer 52 side) of the drift region 12.

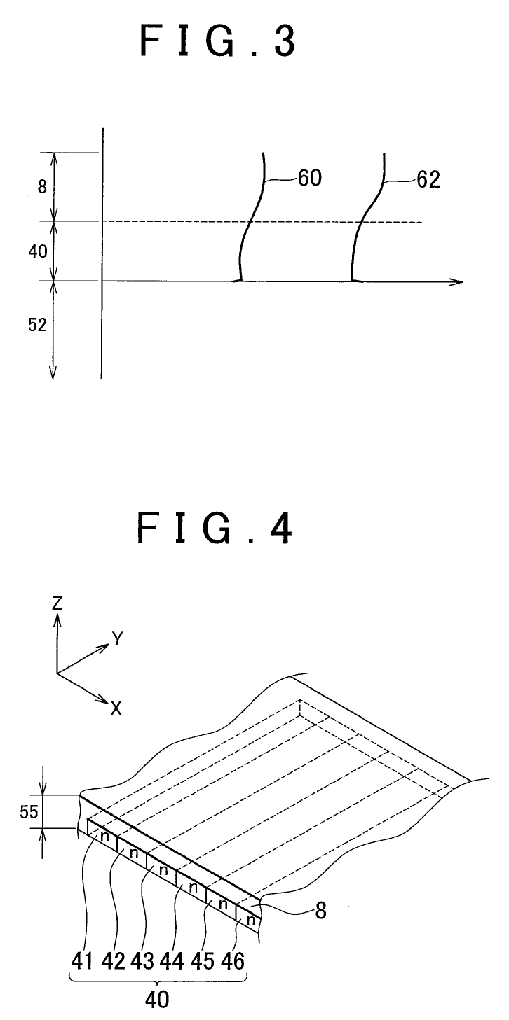

The graph of FIG. 3 schematically shows the electric current distribution in the drift region 12 when the semiconductor device 10 is on. The vertical axis of the graph represents the position in the direction of the depth of the drift region 12, and the horizontal axis represents the electric current (electric current density). Note that the electric current increases toward the right side of the graph. The curve 60 represents the hole current, and the curve 62 represents the electron current. As shown in FIG. 3, the hole current density and the electron current density are both higher in the first layer 8 than in the second layer 40. This indicates that, in the drift region 12, electric density modulations are likely to occur in the layer where the impurity concentration is low, that is, the first layer 8.

According to the semiconductor device 10, as such, because the drift region 12 has the first layer 8 and the second layer 40, the withstand voltage of the semiconductor device 10 in the off state may be increased, and the ON voltage of the semiconductor device 10 may be reduced.

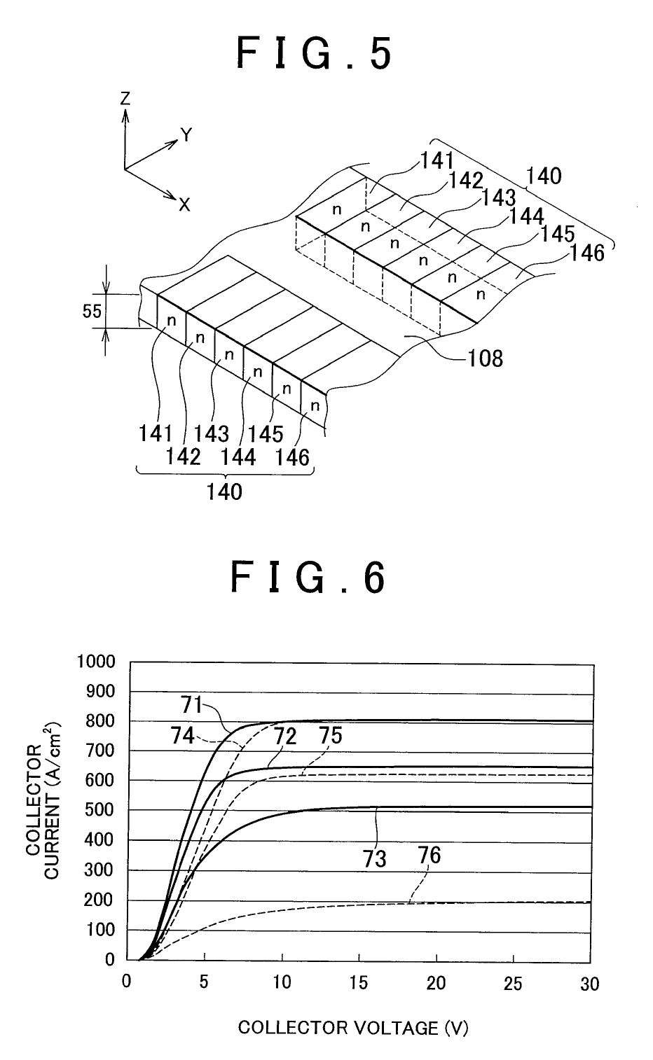

Hereinafter, the positional relation between the first layer 8 and the second layer 40 will be described. FIG. 4 shows a perspective view of the drift region 12 of the semiconductor device 10. Note that FIG. 4 only shows the portion of the drift region 12 where the first layer 8 and the second layer 40 are provided. In FIG. 4, the reference numeral “55” indicates the gap between the implanted insulation layer 52 and the field insulation membrane 6 (Refer to FIG. 1 as well), and the arrows X, Y, and Z indicate coordinates. The X direction runs through the emitter region 24 and the collector region 58. The Y direction and the Z direction are both perpendicular to the X direction. The Z direction indicates the direction of thickness of the buffer region 56. As shown in FIG. 4, the first layer 8 is provided on the second layer 40. That is, the first layer 8 and the second layer 40 are aligned in the Z direction. In this case, the X direction corresponds to “the first direction” cited in the claims and the Z direction corresponds to “the second direction” cited in the claims. The positional relation between the first layer 8 and the second layer 40 is not limited to that shown in FIG. 4. For example, it may be as shown in FIG. 5. Referring to FIG. 5, first layers 108 and second layers 140 are formed such that they extend over the entirety of the gap 55 in the Z direction and such that the first layers 108 and the second layers 140 are alternately arranged in the Y direction. The Y direction is perpendicular to the X direction. Thus, the first layers 108 and the second layers 140 are aligned in the Y direction. In this case, that is, the X direction corresponds to “the first direction” cited in the claims and the Y direction corresponds to “the second direction” cited in the claims.

A comparison was made between the ON voltage (V) of the semiconductor device 10 and the ON voltage of a semiconductor device 300 shown in FIG. 8. The semiconductor device 300 is a semiconductor device according to a related art and it is characterized in that the impurity concentration in a drift region 312 increases from an emitter region 324 toward a collector region 358. Other portions of the semiconductor device 300 are substantially the same as those of the semiconductor device 10, and therefore they are denoted by reference numerals each including the same last two digits as those of the corresponding portion of the semiconductor device 10. During the test, the voltage (ON voltage) that was applied between the emitter and the collector when the electric current density between the emitter and the collector reached a predetermined value (50 A/cm², 100 A/cm², 150 A/cm²) was measured. Further, the length of the body region that partitions the emitter region from the drift region was set to three lengths (1.0 μm, 1.5 μm, 2.0 μm), and the ON voltage was measured each time. Note that the withstand voltage of the semiconductor device 10 is 692 V and the withstand voltage of the semiconductor device 300 is 675 V. That is, the withstand voltage of the semiconductor device 10 and the withstand voltage of the semiconductor device 300 are substantially equal to each other. Table 1 shows the results of the test.

TABLE 1
(Volt)

| | | Emitter-Collector | | |
|---|---|---|---|---|
| | | Current | | |
| | | (A/cm²) | | |
| | | 50 | 100 | 150 |
| Semiconductor | Gate length 1.0 μm | 1.5 | 1.9 | 2.1 |
| Device 10 | Gate length 1.5 μm | 1.6 | 2.0 | 2.3 |
| | Gate length 2.0 μm | 1.7 | 2.3 | 2.8 |
| Semiconductor | Gate length 1.0 μm | 1.9 | 2.4 | 2.8 |
| device 300 | Gate length 1.5 μm | 2.1 | 2.6 | 3.1 |
| | Gate length 2.0 μm | 2.7 | 4.6 | 7.7 |

As shown in Table 1 above, the ON voltage of the semiconductor device 10 is lower than the ON voltage of the semiconductor device 300 when the gate length of the semiconductor device 10 and the gate length of the semiconductor device 300 are equal to each other. The difference in ON voltage between the semiconductor device 10 and the semiconductor device 300 increases with increasing electric current density between the emitter and he collector. Thus, the test shows that the ON voltage of the semiconductor device 10 may be set lower than that of the semiconductor device 300. In particular, the ON voltage of the semiconductor device 10 may be set low when large electric current is applied to the semiconductor device 10.

A comparison was made between the current-voltage characteristic of the semiconductor device 10 and that of the semiconductor device 300. The vertical axis of the graph of FIG. 6 represents the current density (A/cm²) between the emitter and the collector, and the horizontal axis represents the voltage (V) applied between the emitter and the collector. Furthermore, in this test the gate length was set to three lengths, that is, 1.0 μm, 1.5 μm, and 2.0 μm. In the graph, the curve 71 represents the test result obtained with the semiconductor device 10 when the gate length of the semiconductor device 10 was set to 1.0 μm, the curve 72 represents the test result obtained with the semiconductor device 10 when the gate length of the semiconductor device 10 was set to 1.5 μm, the curve 73 represents the test result obtained with the semiconductor device 10 when the gate length of the semiconductor device 10 was set to 2.0 μm, the curve 74 represents the test result obtained with the semiconductor device 300 when the gate length of the semiconductor device 300 was set to 1.0 μm, the curve 75 represents the test result obtained with the semiconductor device 300 when the gate length of the semiconductor device 300 was set to 1.5 μm, and the curve 76 represents the test result obtained with the semiconductor device 300 when the gate length of the semiconductor device 300 was set to 2.0 μm. The voltage applied to the gate electrode was 15V in each test.

Referring to FIG. 6, as indicated by the curves 71, 74, the maximum value of the electric current density of the semiconductor device 10 and the maximum value of the electric current density of the semiconductor device 300 are almost equal to each other when their gate lengths are 1.0 μm. However, the gradient of the electric current density of the semiconductor device 10 to its maximum value is larger than that of the semiconductor device 300. That is, the switching characteristic of the semiconductor device 10 is better than that of the semiconductor device 300. This tendency was found when the gate lengths of the semiconductor device 10 and the semiconductor device 300 were set to 1.5 μm. On the other hand, when the gate lengths of the semiconductor device 10 and the semiconductor device 300 were set to 2.0 μm, the maximum value of the electric current density of the semiconductor device 10 is higher than that of the semiconductor device 300. That is, because the drift region 12 of the semiconductor device 10 has the first layer 8, electric conductivity modulations easily occur in the drift region 12, and therefore the current flowing in the drift region 12 increases. Thus, a larger electric current may be applied to the semiconductor device 10 as compared to the semiconductor device 300.

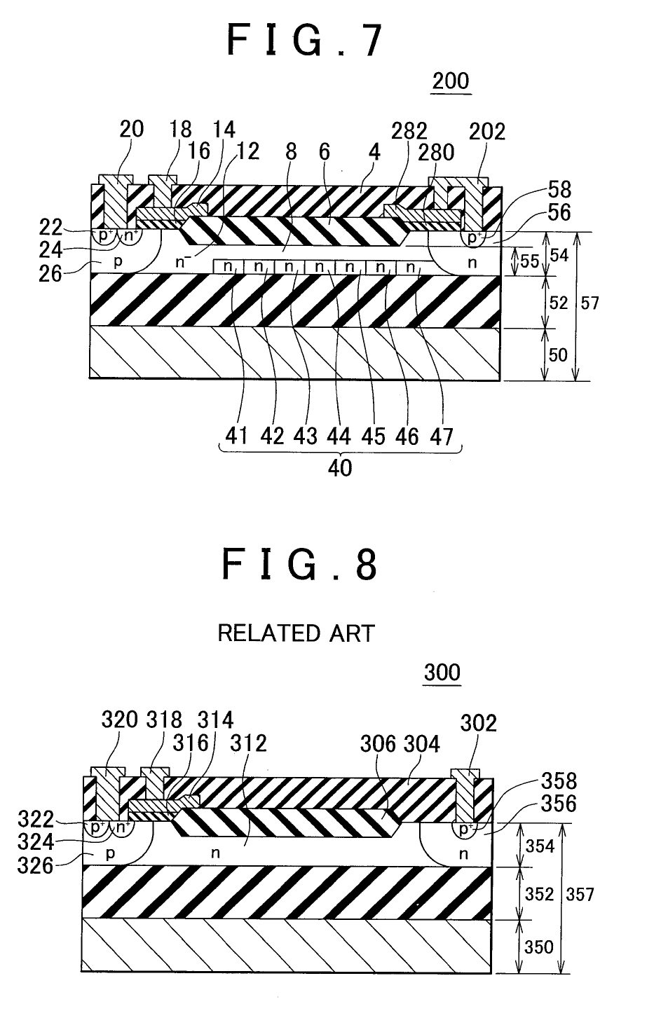

FIG. 7 shows the cross section of semiconductor device 200, which is a modified version of the semiconductor device 10. Insulation membranes 280 are provided on portions of the upper faces of the drift region 12 and the buffer region 56. Field plates 282 are provided on the upper face of a field insulation membrane 6 and the upper surfaces of the insulation membranes 280. The field plates 282 are electrically connected to a collector electrode 202. In the semiconductor device 200, thus, the field plates 282 are energized with the voltage applied to the collector region 58, and this prevents local electric field concentrations near the collector region 58, and therefore the withstand voltage of the semiconductor device can be increased.

Although the invention has been described with reference to example embodiments thereof, it is to be understood that the invention is not restricted to the described embodiments or constructions. The invention is intended to cover various modifications and equivalent arrangements. In addition, while the various elements of the described invention are shown in various example combinations and configurations, other combinations and configurations, including more, less or only a single element, are also within the scope of the appended claims.

What is claimed is:

1. A lateral bipolar semiconductor device, comprising:
a semiconductor layer;
a first main electrode that is provided over a portion of the upper face of the semiconductor layer; and
a second main electrode that is provided over another portion of the upper face of the semiconductor layer, wherein
the semiconductor layer includes a first semiconductor region of a first conductivity type that is in contact with the first main electrode; a second semiconductor region of a second conductivity type that is in contact with the second main electrode; and a third semiconductor region of the first conductivity type that is provided between the first semiconductor region and the second semiconductor region, and wherein
the third semiconductor region includes a first layer and a second layer that extend in a first direction running through the first semiconductor region and the second semiconductor region and that are aligned in a second direction, perpendicular to the first direction;
the impurity concentration in the first layer is uniform in the first direction; and
the impurity concentration in the second layer is higher than that in the first layer, and the impurity concentration in the second layer increases in a gradient from the first semiconductor region side to the second semiconductor region side.

2. The lateral bipolar semiconductor device according to claim 1, wherein
the semiconductor layer is an active layer of a laminated substrate constituted of a semiconductor substrate, an implanted insulation layer, and an active layer.

3. The lateral bipolar semiconductor device according to claim 2, wherein
the second layer is in contact with the implanted insulation layer, and the first layer is provided on the second layer.

4. The lateral bipolar semiconductor device according to claim 2, wherein
the second direction includes a laminating direction of the laminated substrate and a planar direction of each layer of the laminated substrate.

5. The lateral bipolar semiconductor device according to claim 1, wherein
the impurity concentration in the second layer increases in a discontinuous gradient from the first semiconductor side to the second semiconductor side.

6. The lateral bipolar semiconductor device according to claim 1, wherein
the impurity concentration in the second layer increases in a continuous gradient from the first semiconductor side to the second semiconductor side.
